(19) United States
(12) Patent Application Publication
(10) Pub. No.: US 2025/0357088 A1
(43) Pub. Date: Nov. 20, 2025

(54) PLASMA PROCESSING APPARATUS

(71) Applicant: Tokyo Electron Limited, Tokyo (JP)

(72) Inventors: Kewei HU, Miyagi (JP); Tetsuya OHISHI, Miyagi (JP)

(73) Assignee: Tokyo Electron Limited, Tokyo (JP)

(21) Appl. No.: 19/291,683

(22) Filed: Aug. 6, 2025

Related U.S. Application Data
(63) Continuation of application No. PCT/JP2024/001422, filed on Jan. 19, 2024.

(30) Foreign Application Priority Data
Feb. 14, 2023 (JP) 2023-020807

(51) Int. Cl. H01J 37/32

(52) U.S. Cl. CPC H01J 37/32568; H01J 37/32146; H01J 37/32715; H01J 2237/2007

(57) ABSTRACT

A plasma processing apparatus includes a plasma processing chamber; a substrate support including a conductive base, an electrostatic chuck disposed on the conductive base, a chuck electrode disposed in the electrostatic chuck, and a bias electrode disposed below the chuck electrode; an upper electrode that is disposed above the substrate support; an RF generator that is electrically connected to the conductive base, the bias electrode, or the upper electrode and that is configured such that an RF signal is generated; a pulsed DC generator that is electrically connected to the bias electrode and that is configured to generate a pulsed DC signal; an RF filter that is connected between the bias electrode and the pulsed DC generator; and a ringing suppression circuit that is connected between the bias electrode and the pulsed DC generator and that is configured to suppress ringing superimposed on the pulsed DC signal.

### CROSS-REFERENCE TO RELATED APPLICATIONS

This application is a bypass continuation application of international application No. PCT/JP2024/001422 having an international filing date of Jan. 19, 2024 and designating the United States, the international application being based upon and claiming the benefit of priority from Japanese Patent Application No. 2023-020807, filed on Feb. 14, 2023, the entire contents of each of which are incorporated herein by reference.

### BACKGROUND

### Field

An exemplary embodiment of the present disclosure relates to a plasma processing apparatus.

### Description of Related Art

U.S. Patent Application Laid-Open No. 2022/0037119 discloses a technique for performing plasma processing using a pulse voltage in a plasma processing apparatus.

### SUMMARY

A plasma processing apparatus in one exemplary embodiment of the present disclosure includes a plasma processing chamber; a substrate support that is disposed in the plasma processing chamber, the substrate support including a conductive base, an electrostatic chuck disposed on the conductive base, a chuck electrode disposed in the electrostatic chuck, and a bias electrode disposed below the chuck electrode in the electrostatic chuck; an upper electrode that is disposed above the substrate support; an RF generator that is electrically connected to the conductive base, the bias electrode, or the upper electrode and that is configured such that an RF signal is generated; a pulsed DC generator that is electrically connected to the bias electrode and that is configured to generate a pulsed DC signal; an RF filter that is connected between the bias electrode and the pulsed DC generator; and a ringing suppression circuit that is connected between the bias electrode and the pulsed DC generator and that is configured to suppress ringing superimposed on the pulsed DC signal.

### BRIEF DESCRIPTION OF DRAWINGS

FIG. 1 is a diagram for describing a configuration example of a plasma processing system.

FIG. 2 is a diagram for describing a configuration example of a capacitively coupled plasma processing apparatus.

FIG. 3 is a diagram illustrating a configuration example of a substrate support and a power supply in a first exemplary embodiment.

FIG. 4 is a diagram illustrating a configuration example of a first ringing suppression circuit.

FIG. 5 is a diagram illustrating an example of a sequence of first voltage pulses.

FIG. 6 is a diagram illustrating a result of measuring a substrate potential on an electrostatic chuck to which a pulsed DC signal is applied in a case where a ferrite core is disposed as the ringing suppression circuit between a pulsed DC generator and a substrate bias electrode and in a case where the ferrite core is not disposed.

FIG. 7 is a diagram illustrating an ion energy distribution function on a substrate during plasma processing in a case where the ferrite core is not present.

FIG. 8 is a diagram illustrating an ion energy distribution function on the substrate during plasma processing in a case where the ferrite core is present.

FIG. 9 is a graph illustrating results of measuring etching rates of the substrate in etching processing for a case where the ferrite core is present and a case where the ferrite core is not present.

FIG. 10 is a diagram illustrating a configuration example of a first ringing suppression circuit having a plurality of conductors.

FIG. 11 is a diagram illustrating a configuration example of a substrate support and a power supply in a second exemplary embodiment.

FIG. 12 is a diagram illustrating a configuration example of a second ringing suppression circuit.

FIG. 13 is a diagram illustrating an example of a sequence of second voltage pulses.

### DETAILED DESCRIPTION

Hereinafter, each embodiment of the present disclosure will be described.

In an exemplary embodiment, a plasma processing apparatus is provided, the plasma processing apparatus including a plasma processing chamber; a substrate support that is disposed in the plasma processing chamber, the substrate support including a conductive base, an electrostatic chuck disposed on the conductive base, a chuck electrode disposed in the electrostatic chuck, and a bias electrode disposed below the chuck electrode in the electrostatic chuck; an upper electrode that is disposed above the substrate support; an RF generator that is electrically connected to the conductive base, the bias electrode, or the upper electrode and that is configured such that an RF signal is generated; a pulsed DC generator that is electrically connected to the bias electrode and that is configured to generate a pulsed DC signal; an RF filter that is connected between the bias electrode and the pulsed DC generator; and a ringing suppression circuit that is connected between the bias electrode and the pulsed DC generator and that is configured to suppress ringing superimposed on the pulsed DC signal.

In one exemplary embodiment, the ringing suppression circuit includes at least one ferrite core.

In one exemplary embodiment, the ringing suppression circuit includes a plurality of conductors connected in parallel to each other, and a plurality of ferrite cores, each of the plurality of conductors having at least one of the plurality of ferrite cores disposed thereon.

In one exemplary embodiment, the pulsed DC signal has a sequence of voltage pulses.

In one exemplary embodiment, the sequence of the voltage pulses has a voltage level of a negative polarity.

In one exemplary embodiment, the sequence of the voltage pulses has a pulse frequency in a range of 100 kHz to 1 MHz.

In one exemplary embodiment, the pulsed DC signal has a sequence of voltage pulses having a first voltage level in a first period in each cycle and a second voltage level in a second period in each cycle, and an absolute value of the first voltage level is larger than an absolute value of the second voltage level.

In one exemplary embodiment, the first voltage level has a negative polarity.

In one exemplary embodiment, the sequence of the voltage pulses has a pulse frequency in a range of 100 kHz to 1 MHz.

In one exemplary embodiment, the second voltage level has a zero voltage level.

In an exemplary embodiment, a plasma processing apparatus is provided, the plasma processing apparatus including a plasma processing chamber; a substrate support that is disposed in the plasma processing chamber, the substrate support including a base, an electrostatic chuck that is disposed on the base and that has a substrate support surface and an edge ring support surface, an edge ring that is disposed on the edge ring support surface such that the substrate support surface is surrounded, a substrate bias electrode that is disposed below the substrate support surface in the electrostatic chuck, and an edge ring bias electrode that is disposed below the edge ring support surface in the electrostatic chuck; an RF generator that is configured to generate an RF signal for forming a plasma in the plasma processing chamber; a first pulsed DC generator that is electrically connected to the substrate bias electrode and that is configured to generate a first pulsed DC signal; a first RF filter that is connected between the substrate bias electrode and the first pulsed DC generator; a first ringing suppression circuit that is connected between the substrate bias electrode and the first pulsed DC generator and that is configured to suppress ringing superimposed on the first pulsed DC signal; a second pulsed DC generator that is electrically connected to the edge ring bias electrode and that is configured to generate a second pulsed DC signal; a second RF filter that is connected between the edge ring bias electrode and the second pulsed DC generator; and a second ringing suppression circuit that is connected between the edge ring bias electrode and the second pulsed DC generator and that is configured to suppress ringing superimposed on the second pulsed DC signal.

In one exemplary embodiment, the first ringing suppression circuit includes at least one first ferrite core.

In one exemplary embodiment, the second ringing suppression circuit includes at least one second ferrite core.

In one exemplary embodiment, the second ringing suppression circuit includes a plurality of second conductors connected in parallel to each other, and a plurality of second ferrite cores, each of the plurality of second conductors having at least one of the plurality of second ferrite cores disposed thereon.

In one exemplary embodiment, the first ringing suppression circuit includes a plurality of first conductors connected in parallel to each other, and a plurality of first ferrite cores, each of the plurality of first conductors having at least one of the plurality of first ferrite cores disposed thereon.

In one exemplary embodiment, the second ringing suppression circuit includes at least one second ferrite core.

In one exemplary embodiment, the second ringing suppression circuit includes a plurality of second conductors connected in parallel to each other, and a plurality of second ferrite cores, each of the plurality of second conductors having at least one of the plurality of second ferrite cores disposed thereon.

In an exemplary embodiment, a plasma processing apparatus is provided, the plasma processing apparatus including: a plasma processing chamber; a substrate support that is disposed in the plasma processing chamber, the substrate support including a base, an electrostatic chuck disposed on the base, and a bias electrode disposed in the electrostatic chuck; an RF generator that is configured such that an RF signal for forming a plasma is generated in the plasma processing chamber; a pulsed DC generator that is electrically connected to the bias electrode and that is configured to generate a pulsed DC signal; and a ringing suppression circuit that is connected between the bias electrode and the pulsed DC generator and is configured to suppress superimposition of ringing occurring between a first parasitic capacitance and a second parasitic capacitance on the pulsed DC signal, the first parasitic capacitance occurring between the bias electrode and a ground potential, and the second parasitic capacitance occurring between a node on a path from the pulsed DC generator to the bias electrode and the ground potential.

In one exemplary embodiment, the ringing suppression circuit includes at least one ferrite core.

In one exemplary embodiment, the ringing suppression circuit includes a plurality of conductors connected in parallel to each other, and a plurality of ferrite cores, each of the plurality of conductors having at least one of the plurality of ferrite cores disposed thereon.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Plasma Processing Apparatus

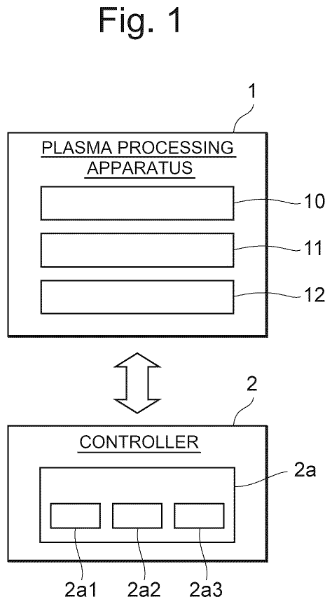

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40 described later. The substrate support 11 is disposed in the plasma processing space and has a substrate support surface for supporting a substrate.

The plasma generator 12 is configured such that a plasma is formed from at least one processing gas supplied into the plasma processing space. The plasma formed in the plasma processing space may be a capacitively coupled plasma (CCD), an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHZ. Therefore, the AC signal includes a radio frequency (RF) signal and a microwave signal. In an embodiment, the RF signal has a frequency in the range of 100 KHz to 150 MHz.

The controller 2 processes a computer-executable instruction that causes the plasma processing apparatus 1 to execute various steps described in the present disclosure. The controller 2 may be configured such that each element of the plasma processing apparatus 1 is controlled such that the various steps described here are executed. In an embodiment, a part or the entirety of the controller 2 may be included in the plasma processing apparatus 1. The controller 2 may include, for example, a computer 2a. The computer 2a may include, for example, a processor (central processing unit (CPU)) 2a1, a storage 2a2, and a communication interface 2a3. The processor 2a1 may be configured to read out a program from the storage 2a2 and execute the read out program such that various control operations are performed. This program may be stored in the storage 2a2 in advance or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

The functionality of the controller 2 may be implemented using circuitry or processing circuitry which includes general purpose processors, special purpose processors, integrated circuits, ASICs (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry is hardware that carries out or is programmed to perform the recited functionality. The hardware may be any hardware disclosed herein which is programmed or configured to carry out the recited functionality.

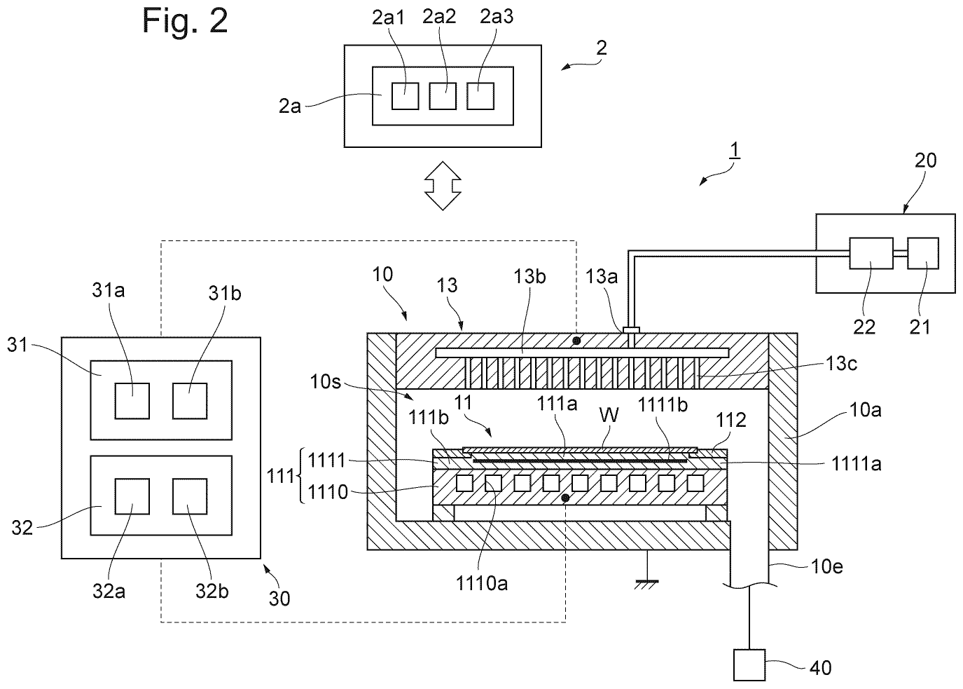

Hereinafter, a configuration example of the capacitively coupled plasma processing apparatus as an example of the plasma processing apparatus 1 will be described. FIG. 2 is a diagram for describing a configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured such that at least one processing gas is introduced into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 such that the substrate W on the center region 111a of the main body 111 is surrounded. Therefore, the center region 111a is also referred to as a substrate support surface for supporting the substrate W, and the annular region 111b is also referred to as an edge ring support surface for supporting the ring assembly 112.

In an embodiment, the main body 111 includes a base 1110 and an electrostatic chuck 1111. The base 1110 includes a conductive member and may be a conductive base. The conductive member of the base 1110 may function as a lower electrode. The electrostatic chuck 1111 is disposed on the base 1110. The electrostatic chuck 1111 includes a ceramic member 1111a and an electrostatic electrode (chuck electrode) 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. In addition, an RF or DC electrode may be disposed in the ceramic member 1111a, and in this case, the RF or DC electrode functions as a lower electrode. In a case where a bias RF signal or a DC signal, described later, is connected to the RF or DC electrode, the RF or DC electrode is referred to as a bias electrode. Both of the conductive member of the base 1110 and the RF or DC electrode may function as two lower electrodes.

The ring assembly 112 includes one or more annular members. In an embodiment, one or more annular members include one or more edge rings and at least one cover ring. The edge ring is formed of a conductive material or an insulating material, and the cover ring is formed of an insulating material.

In addition, the substrate support 11 may include a temperature-controlled module configured such that at least one of the electrostatic chuck 1111, the ring assembly 112, and the substrate is adjusted to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or more heaters are disposed in the ceramic member 1111a of the electrostatic chuck 1111. Further, the substrate support 11 may include a heat transfer gas supply configured such that the heat transfer gas is supplied to a gap between a back surface of the substrate W and the center region 111a.

The shower head 13 is configured such that at least one processing gas is introduced from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes an upper electrode. In addition to the shower head 13, the gas introducer may include one or more side gas injectors (SGI) attached to one or more opening portions formed on the side wall 10a.

The gas supply 20 may include at least one gas source 21 and at least one flow rate controller 22. In an embodiment, the gas supply 20 is configured such that at least one processing gas is supplied to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes an RF power supply 31 coupled to the plasma processing chamber 10 via at least one impedance matching circuit. The RF power supply 31 is configured such that at least one RF signal (RF power), such as a source RF signal and a bias RF signal, is supplied to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma can be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured such that a source RF signal (source RF power) for plasma formation is generated. In an embodiment, the source RF signal has a frequency in the range of 10 MHz to 150 MHZ. In an embodiment, the first RF generator 31a may be configured such that a plurality of source RF signals having different frequencies are generated. The generated one or more source RF signals are supplied to at least one lower electrode and/or at least one upper electrode.

The second RF generator 31b is coupled to at least one lower electrode via at least one impedance matching circuit and is configured such that the bias RF signal (bias RF power) is generated. The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured such that a plurality of bias RF signals having different frequencies are generated. The generated one or more bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode and is configured such that the first DC signal is generated. The generated first DC signal is applied to at least one lower electrode. In an embodiment, the second DC generator 32b is connected to at least one upper electrode and is configured such that a second DC signal is generated. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or more voltage pulses of a positive polarity and one or more voltage pulses of a negative polarity in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### First Exemplary Embodiment

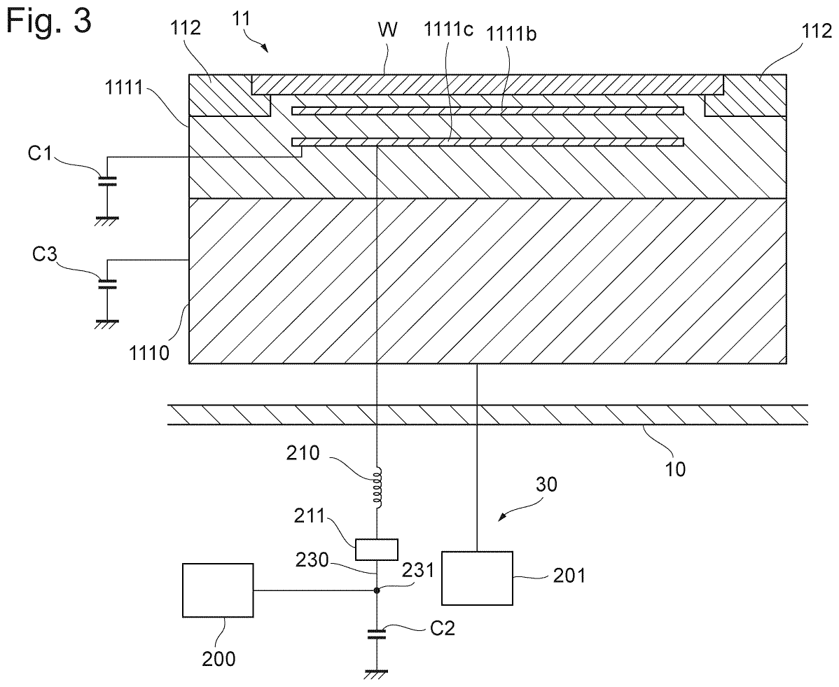

FIG. 3 illustrates a configuration example of the substrate support 11 and the power supply 30 in a first exemplary embodiment. In an embodiment, the substrate support 11 has the chuck electrode 1111b and a substrate bias electrode 1111c inside the electrostatic chuck 1111. The substrate bias electrode 1111c may be disposed below the chuck electrode 1111b. A first pulsed DC generator 200 that generates the first pulsed DC signal is electrically connected to the substrate bias electrode 1111c. The first pulsed DC generator 200 may be an example of the first DC generator 32a. The RF generator 201 that generates the RF signal is electrically connected to the base 1110. The RF generator 201 may be an example of the first RF generator 31a and/or the second RF generator 31b described above. In an embodiment, the RF generator 201 may be connected to the substrate bias electrode 1111c.

In an embodiment, a first RF filter 210 and a first ringing suppression circuit 211 are connected between the substrate bias electrode 1111c and the first pulsed DC generator 200. The substrate bias electrode 1111c is grounded, and a first parasitic capacitance C1 may be generated between the substrate bias electrode 1111c and the ground potential. A path 230 from the first pulsed DC generator 200 to the substrate bias electrode 1111c is grounded, and a second parasitic capacitance C2 may be generated between a node 231 on the path 230 and the ground potential. Furthermore, the base 1110 is grounded, and a third parasitic capacitance C3 may be generated between the base 1110 and the ground potential.

In an embodiment, the first RF filter 210 is configured such that the RF signal supplied from the RF generator 201 to the base 1110 is suppressed from entering the first pulsed DC generator 200 via the path 230. The first RF filter 210 may remove a signal of a specific frequency corresponding to a frequency of the RF signal. The first RF filter 210 may be a coil. The first RF filter 210 may be disposed outside the chamber 10.

Due to a coil inductance of the first RF filter 210, resonance may occur between the first parasitic capacitance C1 and the second parasitic capacitance C2, and ringing (RF component) may occur in the first pulsed DC signal supplied from the first pulsed DC generator 200. In an embodiment, the first ringing suppression circuit 211 is configured such that ringing superimposed on the first pulsed DC signal is suppressed. The first ringing suppression circuit 211 may be provided outside the chamber 10. The first ringing suppression circuit 211 may be connected between the first RF filter 210 and the first pulsed DC generator 200. The first ringing suppression circuit 211 may be connected between the first RF filter 210 and the substrate bias electrode 1111c.

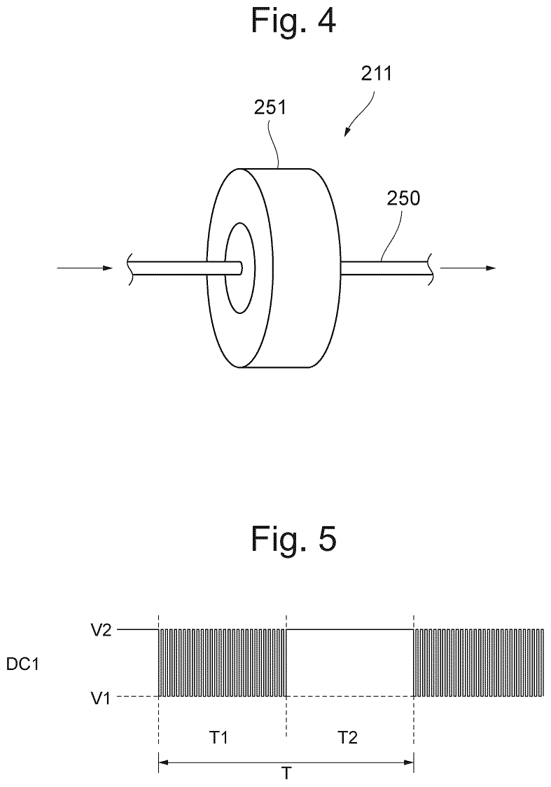

In an embodiment, as illustrated in FIG. 4, the first ringing suppression circuit 211 includes a first conductor 250 connected to the path 230 and a first ferrite core 251 disposed on the first conductor 250. The first ferrite core 251 may remove ringing superimposed on a first pulsed DC signal.

In an embodiment, the first pulsed DC signal of the first pulsed DC generator 200 has a sequence of voltage pulses. FIG. 5 illustrates an example of a sequence DC1 of first voltage pulses generated by the first pulsed DC generator 200. The sequence DC1 of the first voltage pulses has a pulse frequency in a range of 100 kHz to 1 MHz. The sequence DC1 of the first voltage pulses has a repetition cycle T. The sequence DC1 of the first voltage pulses may have a first voltage level V1 in a first period T1 in each cycle T and may have a second voltage level V2, which is a reference voltage level, in a second period T2 in each cycle T. An absolute value of the first voltage level V1 is larger than an absolute value of the second voltage level V2. In an embodiment, the first voltage level V1 has a negative polarity. In an embodiment, the second voltage level V2 has a zero voltage level. In an embodiment, the first voltage level V1 is 0 V to −15 kV.

### Example of Plasma Processing Method

The plasma processing performed using the plasma processing apparatus 1 includes etching processing of etching a film on the substrate W using plasma. In an embodiment, the plasma processing is executed by the controller 2.

First, the substrate W is transported into the chamber 10 by the transport arm, placed on the substrate support 11 by a lifter, and is held by suction on the substrate support 11 as illustrated in FIG. 2.

Next, the processing gas is supplied to the shower head 13 by the gas supply 20 and is supplied from the shower head 13 to the plasma processing space 10s. The processing gas supplied at this time includes a gas that generates an active species required for the etching processing of the substrate W.

In an embodiment, the source RF signal for plasma formation is supplied to the lower electrode and/or the upper electrode. A bias signal for ion drawing may be supplied to the lower electrode. In this case, the atmosphere in the plasma processing space 10s is exhausted from the gas exhaust port 10e, and the inside of the plasma processing space 10s may be depressurized to a predetermined pressure. As a result, plasma is formed in the plasma processing space 10s, and the substrate W is subjected to the etching processing.

In an example of the plasma processing, the RF signal is supplied to the base 1110 illustrated in FIG. 3 by the RF generator 201. The first pulsed DC signal is applied as the bias signal to the substrate bias electrode 1111c by the first pulsed DC generator 200. In this case, the first RF filter 210 suppresses the RF signal supplied from the RF generator 201 to the base 1110 from entering the first pulsed DC generator 200 via the path 230. In addition, the first ringing suppression circuit 211 suppresses the superimposition of the ringing generated between the first parasitic capacitance C1 and the second parasitic capacitance C2 on the first pulsed DC signal.

According to the present exemplary embodiment, the plasma processing apparatus 1 includes the base 1110, the RF generator 201, the first pulsed DC generator 200, the first RF filter 210, and the first ringing suppression circuit 211. As a result, it is possible to suppress the superimposition of the ringing on the pulsed DC signal applied to the substrate bias electrode 1111c from the first pulsed DC generator 200. Therefore, it is possible to appropriately perform the plasma processing using the pulsed DC signal.

### EXAMPLES

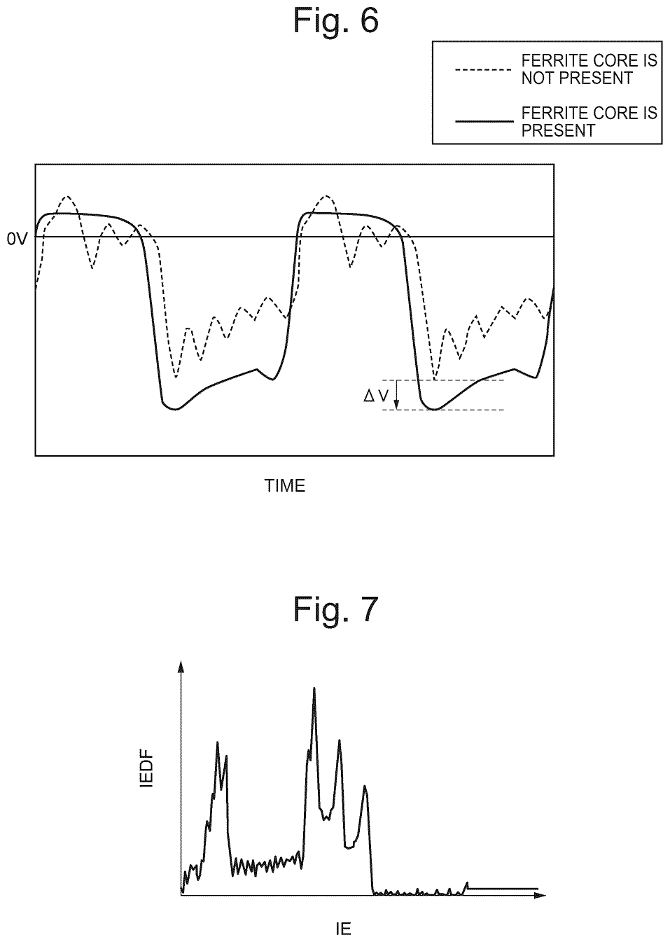

For a case where a ferrite core was disposed between the pulsed DC generator and the substrate bias electrode (the ferrite core is present) and a case where the ferrite core was not disposed (the ferrite core is not present) as the ringing suppression circuit, the substrate potential on the electrostatic chuck to which the pulsed DC signal was applied was measured. FIG. 6 illustrates a measurement result. It is possible to confirm that the substrate potential in a case where the ferrite core is present is close to the rectangular waveform of the pulsed DC signal, and the ringing (RF component) superimposed on the pulsed DC signal is reduced compared to a case where the ferrite core is not present. In addition, it is possible to confirm that the absolute value of the substrate potential in a case where the ferrite core is present is high compared to a case where the ferrite core is not present (ΔV in FIG. 6). As a result, in a case where the ferrite core is present, it is possible to confirm that the electric energy of the pulsed DC signal is efficiently transmitted to the substrate.

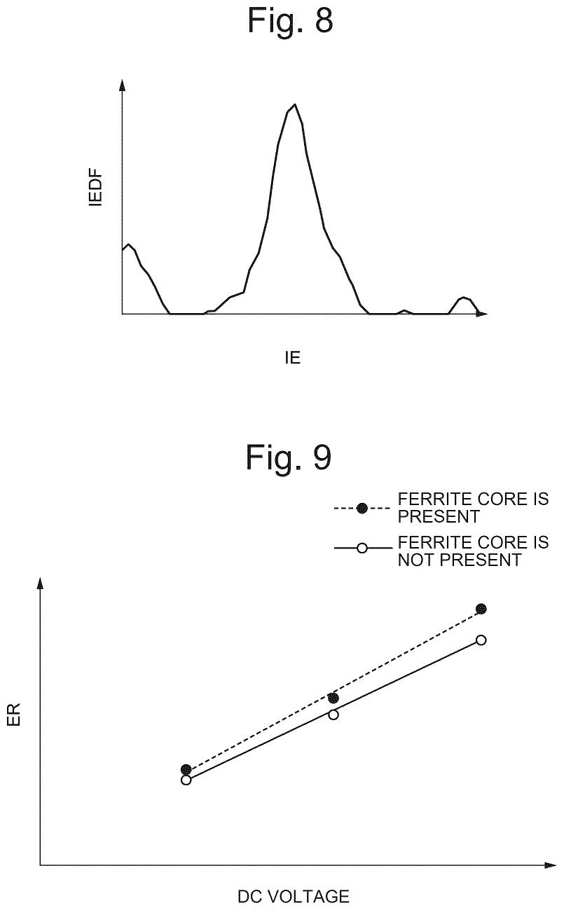

FIG. 7 illustrates an ion energy distribution function (IEDF) on the substrate during the plasma processing in a case where the ferrite core is not present. FIG. 8 illustrates an ion energy distribution function on the substrate during the plasma processing in a case where the ferrite core is present. In a case where the ferrite core is not present, it is possible to confirm that there are a plurality of peaks of the ion energy distribution function in a region where the ion energy (IE) is high, whereas in a case where the ferrite core is present, it is possible to confirm that there is one peak of the ion energy distribution function in the region where the ion energy (IE) is high. As a result, it can be seen that the ion energy on the substrate is high and stable in a case where the ferrite core is present.

FIG. 9 is a result of measuring an etching rate (ER) of the substrate in the etching processing in a case where the ferrite core is present and a case where the ferrite core is not present. A horizontal axis of FIG. 9 is the DC voltage of the pulsed DC signal. It is possible to confirm that the etching rate in a case where the ferrite core is present is high compared to a case where the ferrite core is not present.

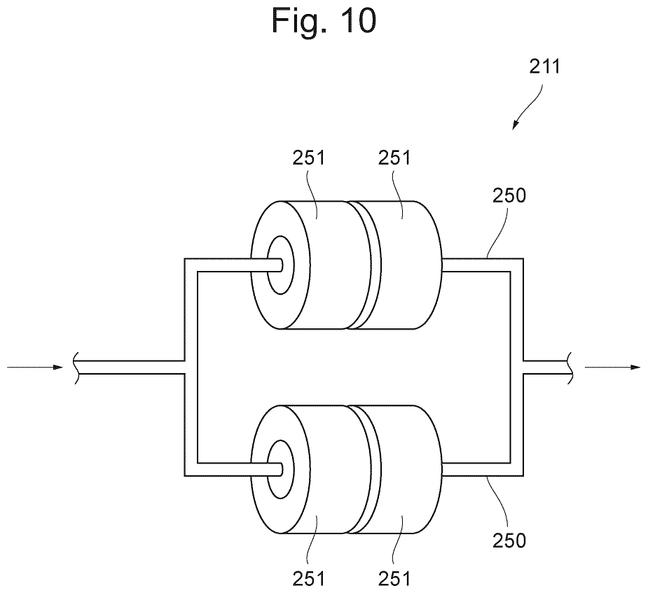

In the above-described embodiment, as illustrated in FIG. 10, the first ringing suppression circuit 211 may have a plurality of first conductors 250 connected in parallel and a plurality of first ferrite cores 251 disposed in each of the plurality of first conductors 250. In an embodiment, the plurality of first ferrite cores 251 may be disposed in each first conductor 250, or one first ferrite core 251 may be disposed. In such a case, the current flowing through each first conductor 250 is reduced by the pulsed DC signal, and as a result, it is possible to suppress the heat generation of the first ferrite core 251 generated by the removal of the ringing.

### Second Exemplary Embodiment

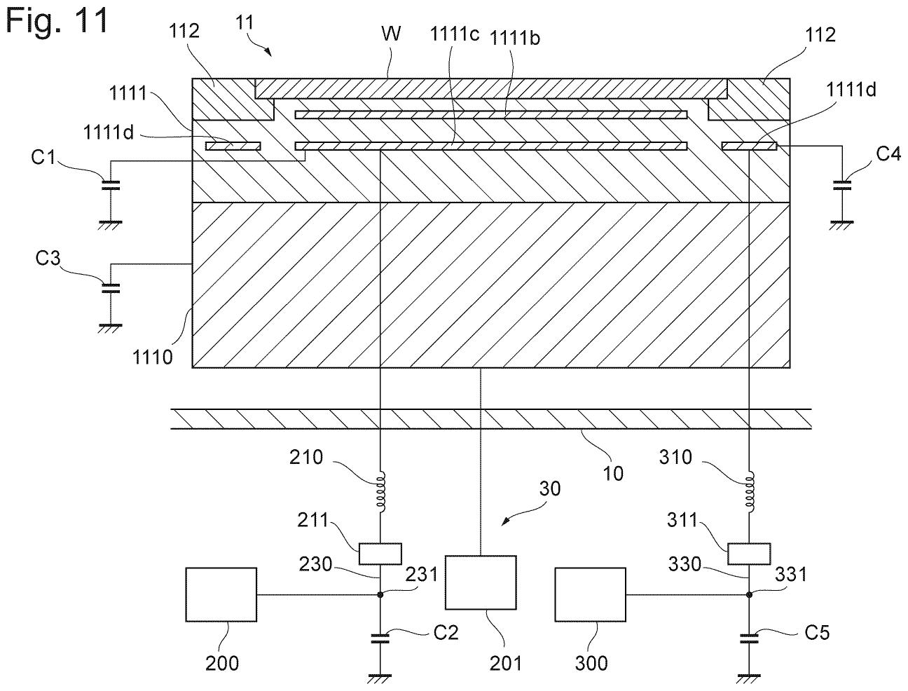

FIG. 11 illustrates a configuration example of the substrate support 11 and the power supply 30 in a second exemplary embodiment. In an embodiment, the substrate support 11 may have an edge ring bias electrode 1111d in addition to the chuck electrode 1111b and the substrate bias electrode 1111c inside the electrostatic chuck 1111. The edge ring bias electrode 1111d may be disposed below the edge ring support surface. A second pulsed DC generator 300 that generates a second pulsed DC signal is electrically connected to the edge ring bias electrode 1111d.

In an embodiment, a second RF filter 310 and a second ringing suppression circuit 311 are connected between the edge ring bias electrode 1111d and the second pulsed DC generator 300. The edge ring bias electrode 1111d is grounded, and a fourth parasitic capacitance C4 may be generated between the edge ring bias electrode 1111d and the ground potential. A path 330 from the second pulsed DC generator 300 to the edge ring bias electrode 1111d is grounded, and a fifth parasitic capacitance C5 may be generated between a node 331 on the path 330 and the ground potential.

In an embodiment, the second RF filter 310 is configured such that the RF signal supplied from the RF generator 201 to the base 1110 is suppressed from entering the second pulsed DC generator 300 via the path 330. The second RF filter 310 may remove a signal of a specific frequency corresponding to the frequency of the RF signal. The second RF filter 310 may be a coil. The second RF filter 310 may be provided outside the chamber 10.

Due to a coil inductance of the second RF filter 310, resonance may occur between the fourth parasitic capacitance C4 and the fifth parasitic capacitance C5, and the ringing (RF component) may occur in the second pulsed DC signal. In an embodiment, the second ringing suppression circuit 311 is configured such that the ringing superimposed on the second pulsed DC signal is suppressed. The second ringing suppression circuit 311 may be provided outside the chamber 10. The second ringing suppression circuit 311 may be connected between the second RF filter 310 and the second pulsed DC generator 300. The second ringing suppression circuit 311 may be connected between the second RF filter 310 and the edge ring bias electrode 1111d.

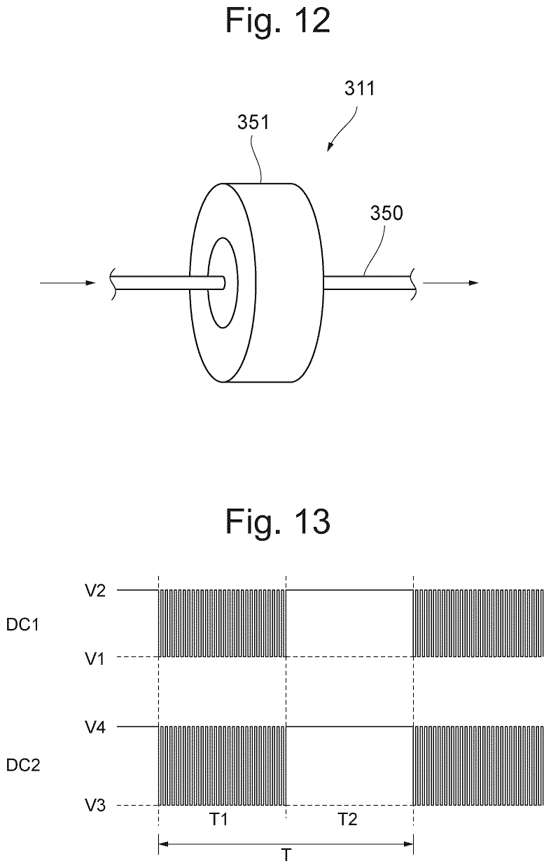

In an embodiment, as illustrated in FIG. 12, the second ringing suppression circuit 311 includes a second conductor 350 connected to the path 330 and a second ferrite core 351 disposed on the second conductor 350. A plurality of second ferrite cores 351 may be disposed in each second conductor 350, or one second ferrite core 351 may be disposed. The second ferrite core 351 may remove the ringing superimposed on a second pulsed DC signal.

The second pulsed DC signal of the second pulsed DC generator 300 has a sequence of voltage pulses. FIG. 13 illustrates an example of a sequence DC2 of the second voltage pulses generated by the second pulsed DC generator 300. The sequence DC2 of the second voltage pulses has a pulse frequency in a range of 100 kHz to 1 MHz. In an embodiment, the sequence DC2 of the second voltage pulses has the same repetition cycle T as the sequence DC1 of the first voltage pulses. The sequence DC2 of the second voltage pulses may have a third voltage level V3 in the first period T1 in each cycle T and may have a fourth voltage level V4, which is the reference voltage level, in the second period T2 of each cycle T. An absolute value of the third voltage level V3 is larger than an absolute value of the fourth voltage level V4. In an embodiment, the third voltage level V3 has a negative polarity. In an embodiment, the fourth voltage level V4 has the zero voltage level. In an embodiment, the third voltage level V3 is 0 V to −15 kV.

Other configurations of the substrate support 11 and the power supply 30 in the second exemplary embodiment may be the same as those in the first exemplary embodiment.

According to the present exemplary embodiment, it is possible to suppress the superimposition of the ringing on the pulsed DC signal applied to the edge ring bias electrode 1111d from the second pulsed DC generator 300. Therefore, it is possible to appropriately perform the plasma processing using the pulsed DC signal.

In the above-described embodiment, the ringing suppression circuit may have a damping resistor instead of the ferrite core or together with the ferrite core.

For example, in the embodiments described above, while the capacitively coupled plasma apparatus is illustratively described, the present disclosure is not limited thereto and may be applied to other plasma apparatuses. For example, an inductively coupled plasma apparatus may be used instead of the capacitively coupled plasma apparatus. In this case, the inductively coupled plasma apparatus includes an antenna and a lower electrode. The lower electrode is disposed in the substrate support, and the antenna is disposed on the upper portion of or above the chamber. In an embodiment, the RF power supply 31 may be electrically connected to the antenna and may supply the RF signal to the antenna.

The embodiments of the present disclosure further include the following aspects.

### (Addendum 1)

A plasma processing apparatus including:
a plasma processing chamber;
a substrate support that is disposed in the plasma processing chamber, the substrate support including a conductive base, an electrostatic chuck disposed on the conductive base, a chuck electrode disposed in the electrostatic chuck, and a bias electrode disposed below the chuck electrode in the electrostatic chuck;
an upper electrode that is disposed above the substrate support;
an RF generator that is electrically connected to the conductive base, the bias electrode, or the upper electrode and is configured such that an RF signal is generated
a pulsed DC generator that is electrically connected to the bias electrode and is configured to generate a pulsed DC signal;
an RF filter that is connected between the bias electrode and the pulsed DC generator; and
a ringing suppression circuit that is connected between the bias electrode and the pulsed DC generator and is configured to suppress ringing superimposed on the pulsed DC signal.

### (Addendum 2)

The plasma processing apparatus according to Addendum 1, in which the ringing suppression circuit includes at least one ferrite core.

### (Addendum 3)

The plasma processing apparatus according to Addendum 1 or 2, in which the ringing suppression circuit includes
a plurality of conductors connected in parallel to each other, and
a plurality of ferrite cores, at least one of which is disposed on each of the plurality of conductors.

### (Addendum 4)

The plasma processing apparatus according to any one of Addenda 1 to 3, in which the pulsed DC signal has a sequence of voltage pulses.

### (Addendum 5)

The plasma processing apparatus according to Addendum 4, in which the sequence of the voltage pulses has a voltage level of a negative polarity.

### (Addendum 6)

The plasma processing apparatus according to Addendum 4 or 5, in which the sequence of the voltage pulses has a pulse frequency in a range of 100 kHz to 1 MHz.

### (Addendum 7)

The plasma processing apparatus according to any one of Addenda 1 to 3, in which
the pulsed DC signal has a sequence of voltage pulses having a first voltage level in a first period in each cycle and a second voltage level in a second period in each cycle, and
an absolute value of the first voltage level is larger than an absolute value of the second voltage level.

### (Addendum 8)

The plasma processing apparatus according to Addendum 7, in which the first voltage level has a negative polarity.

### (Addendum 9)

The plasma processing apparatus according to Addendum 7 or 8, in which the sequence of the voltage pulses has a pulse frequency in a range of 100 kHz to 1 MHz.

### (Addendum 10)

The plasma processing apparatus according to any one of Addenda 7 to 9, in which the second voltage level has a zero voltage level.

### (Addendum 11)

A plasma processing apparatus including:
a plasma processing chamber;
a substrate support that is disposed in the plasma processing chamber, the substrate support including
a base,
an electrostatic chuck that is disposed on the base and has a substrate support surface and an edge ring support surface,
an edge ring that is disposed on the edge ring support surface such that a substrate on the substrate support surface is surrounded,
a substrate bias electrode that is disposed below the substrate support surface in the electrostatic chuck, and
an edge ring bias electrode that is disposed below the edge ring support surface in the electrostatic chuck;
an RF generator that is configured to generate an RF signal for forming a plasma in the plasma processing chamber;
a first pulsed DC generator that is electrically connected to the substrate bias electrode and is configured to generate a first pulsed DC signal;
a first RF filter that is connected between the substrate bias electrode and the first pulsed DC generator;
a first ringing suppression circuit that is connected between the substrate bias electrode and the first pulsed DC generator and is configured to suppress ringing superimposed on the first pulsed DC signal;
a second pulsed DC generator that is electrically connected to the edge ring bias electrode and is configured to generate a second pulsed DC signal;
a second RF filter that is connected between the edge ring bias electrode and the second pulsed DC generator; and
a second ringing suppression circuit that is connected between the edge ring bias electrode and the second pulsed DC generator and is configured to suppress ringing superimposed on the second pulsed DC signal.

### (Addendum 12)

The plasma processing apparatus according to Addendum 11, in which the first ringing suppression circuit includes at least one first ferrite core.

### (Addendum 13)

The plasma processing apparatus according to Addendum 11 or 12, in which the second ringing suppression circuit includes at least one second ferrite core.

### (Addendum 14)

The plasma processing apparatus according to Addendum 11, in which the second ringing suppression circuit includes
a plurality of second conductors connected in parallel to each other, and
a plurality of second ferrite cores, at least one of which is disposed on each of the plurality of second conductors.

### (Addendum 15)

The plasma processing apparatus according to Addendum 11, in which the first ringing suppression circuit includes
a plurality of first conductors connected in parallel to each other, and
a plurality of first ferrite cores, at least one of which is disposed on each of the plurality of first conductors.

### (Addendum 16)

The plasma processing apparatus according to Addendum 15, in which the second ringing suppression circuit includes at least one second ferrite core.

### (Addendum 17)

The plasma processing apparatus according to Addendum 15 or 16, in which the second ringing suppression circuit includes
a plurality of second conductors connected in parallel to each other, and
a plurality of second ferrite cores, at least one of which is disposed on each of the plurality of second conductors.

### (Addendum 18)

A plasma processing apparatus including:
a plasma processing chamber;
a substrate support that is disposed in the plasma processing chamber, the substrate support including a base, an electrostatic chuck disposed on the base, and a bias electrode disposed in the electrostatic chuck;
an RF generator that is configured such that an RF signal for forming a plasma is generated in the plasma processing chamber;
a pulsed DC generator that is electrically connected to the bias electrode and is configured to generate a pulsed DC signal; and
a ringing suppression circuit that is connected between the bias electrode and the pulsed DC generator and is configured to suppress superimposition of ringing occurring between a first parasitic capacitance and a second parasitic capacitance on the pulsed DC signal, the first parasitic capacitance occurring between the bias electrode and a ground potential, and the second parasitic capacitance occurring between a node on a path from the pulsed DC generator to the bias electrode and the ground potential.

### (Addendum 19)

The plasma processing apparatus according to Addendum 18, in which the ringing suppression circuit includes at least one ferrite core.

### (Addendum 20)

The plasma processing apparatus according to Addendum 18 or 19, in which the ringing suppression circuit includes
a plurality of conductors connected in parallel to each other, and
a plurality of ferrite cores, at least one of which is disposed on each of the plurality of conductors.

Each of the above embodiments is described for the purpose of description, and it is not intended to limit the scope of the present disclosure. Each of the above embodiments may be modified in various ways without departing from the scope and gist of the present disclosure. For example, some constitutional elements in one embodiment are able to be added to other embodiments. In addition, some configuration elements in one embodiment are able to be replaced with corresponding configuration elements in another embodiment.

According to one exemplary embodiment of the present disclosure, it is possible to provide a technique for appropriately performing plasma processing using a pulsed DC signal.

What is claimed is:

1. A plasma processing apparatus comprising:
a plasma processing chamber;
a substrate support that is disposed in the plasma processing chamber, the substrate support including:
a conductive base,
an electrostatic chuck disposed on the conductive base,
a chuck electrode disposed in the electrostatic chuck, and
a bias electrode disposed below the chuck electrode in the electrostatic chuck;
an upper electrode that is disposed above the substrate support;
an RF generator that is electrically connected to the conductive base, the bias electrode, or the upper electrode and that is configured such that an RF signal is generated;
a pulsed DC generator that is electrically connected to the bias electrode and that is configured to generate a pulsed DC signal;
an RF filter that is connected between the bias electrode and the pulsed DC generator; and
a ringing suppression circuit that is connected between the bias electrode and the pulsed DC generator and that is configured to suppress ringing superimposed on the pulsed DC signal.

2. The plasma processing apparatus according to claim 1, wherein the ringing suppression circuit includes at least one ferrite core.

3. The plasma processing apparatus according to claim 1, wherein the ringing suppression circuit includes:
a plurality of conductors connected in parallel to each other, and
a plurality of ferrite cores, each of the plurality of conductors having at least one of the plurality of ferrite cores disposed thereon.

4. The plasma processing apparatus according to claim 1, wherein the pulsed DC signal has a sequence of voltage pulses.

5. The plasma processing apparatus according to claim 4, wherein the sequence of the voltage pulses has a voltage level of a negative polarity.

6. The plasma processing apparatus according to claim 5, wherein the sequence of the voltage pulses has a pulse frequency in a range of 100 kHz to 1 MHz.

7. The plasma processing apparatus according to claim 1, wherein
the pulsed DC signal has a sequence of voltage pulses having a first voltage level in a first period in each cycle and a second voltage level in a second period in each cycle, and
an absolute value of the first voltage level is larger than an absolute value of the second voltage level.

8. The plasma processing apparatus according to claim 7, wherein the first voltage level has a negative polarity.

9. The plasma processing apparatus according to claim 8, wherein the sequence of the voltage pulses has a pulse frequency in a range of 100 kHz to 1 MHz.

10. The plasma processing apparatus according to claim 9, wherein the second voltage level has a zero voltage level.

11. A plasma processing apparatus comprising:
a plasma processing chamber;
a substrate support that is disposed in the plasma processing chamber, the substrate support including:
a base,
an electrostatic chuck that is disposed on the base and that has a substrate support surface and an edge ring support surface,
an edge ring that is disposed on the edge ring support surface such that the substrate support surface is surrounded,
a substrate bias electrode that is disposed below the substrate support surface in the electrostatic chuck, and
an edge ring bias electrode that is disposed below the edge ring support surface in the electrostatic chuck;
an RF generator that is configured to generate an RF signal for forming a plasma in the plasma processing chamber;
a first pulsed DC generator that is electrically connected to the substrate bias electrode and that is configured to generate a first pulsed DC signal;
a first RF filter that is connected between the substrate bias electrode and the first pulsed DC generator;
a first ringing suppression circuit that is connected between the substrate bias electrode and the first pulsed DC generator and that is configured to suppress ringing superimposed on the first pulsed DC signal;
a second pulsed DC generator that is electrically connected to the edge ring bias electrode and that is configured to generate a second pulsed DC signal;
a second RF filter that is connected between the edge ring bias electrode and the second pulsed DC generator; and
a second ringing suppression circuit that is connected between the edge ring bias electrode and the second pulsed DC generator and that is configured to suppress ringing superimposed on the second pulsed DC signal.

12. The plasma processing apparatus according to claim 11, wherein the first ringing suppression circuit includes at least one first ferrite core.

13. The plasma processing apparatus according to claim 12, wherein the second ringing suppression circuit includes at least one second ferrite core.

14. The plasma processing apparatus according to claim 11, wherein the second ringing suppression circuit includes:
a plurality of second conductors connected in parallel to each other, and
a plurality of second ferrite cores, each of the plurality of second conductors having at least one of the plurality of second ferrite cores disposed thereon.

15. The plasma processing apparatus according to claim 11, wherein the first ringing suppression circuit includes:
a plurality of first conductors connected in parallel to each other, and
a plurality of first ferrite cores, each of the plurality of first conductors having at least one of the plurality of first ferrite cores disposed thereon.

16. The plasma processing apparatus according to claim 15, wherein the second ringing suppression circuit includes at least one second ferrite core.

17. The plasma processing apparatus according to claim 15, wherein the second ringing suppression circuit includes:
a plurality of second conductors connected in parallel to each other, and
a plurality of second ferrite cores, each of the plurality of second conductors having at least one of the plurality of second ferrite cores disposed thereon.

18. A plasma processing apparatus comprising:
a plasma processing chamber;
a substrate support that is disposed in the plasma processing chamber, the substrate support including:
a base,
an electrostatic chuck disposed on the base, and
a bias electrode disposed in the electrostatic chuck;
an RF generator that is configured such that an RF signal for forming a plasma is generated in the plasma processing chamber;
a pulsed DC generator that is electrically connected to the bias electrode and that is configured to generate a pulsed DC signal; and
a ringing suppression circuit that is connected between the bias electrode and the pulsed DC generator and that is configured to suppress superimposition of ringing occurring between a first parasitic capacitance and a second parasitic capacitance on the pulsed DC signal, the first parasitic capacitance occurring between the bias electrode and a ground potential, and the second parasitic capacitance occurring between a node on a path from the pulsed DC generator to the bias electrode and the ground potential.

19. The plasma processing apparatus according to claim 18, wherein the ringing suppression circuit includes at least one ferrite core.

20. The plasma processing apparatus according to claim 18, wherein the ringing suppression circuit includes:
a plurality of conductors connected in parallel to each other, and
a plurality of ferrite cores, each of the plurality of conductors having at least one of the plurality of ferrite cores disposed thereon.
